(19) United States
(12) Patent Application Publication
(10) Pub. No.: US 2016/0172575 A1
(43) Pub. Date: Jun. 16, 2016

(54) CONDUCTIVE PASTE FOR INTERNAL ELECTRODE, PIEZOELECTRIC ELEMENT, AND PIEZOELECTRIC VIBRATION MODULE INCLUDING THE SAME

(71) Applicant: SAMSUNG ELECTRO-MECHANICS CO., LTD., Suwon-si (KR)

(72) Inventors: Hui Sun PARK, Suwon-Si (KR); Boum Seock KIM, Suwon-Si (KR); Jung Wook SEO, Suwon-Si (KR); Seung Ho LEE, Suwon-Si (KR)

(21) Appl. No.: 14/945,277

(22) Filed: Nov. 18, 2015

(30) Foreign Application Priority Data
Nov. 20, 2014 (KR) 10-2014-0162834

(51) Int. Cl. H01L 41/187; C09D 5/24; H01L 41/09; H01L 41/43; H01L 41/047

(52) U.S. Cl. CPC H01L 41/187; H01L 41/43; H01L 41/0471; H01L 41/09; C09D 5/24

(57) ABSTRACT

A conductive paste for an internal electrode includes a conductive material; and a common material comprising a dielectric substance and a eutectic mixture, wherein the eutectic mixture comprises lead oxide (PbO) and copper oxide (CuO) and has a eutectic temperature that is higher than a sintering temperature of the conductive material.

### CROSS-REFERENCE TO RELATED APPLICATIONS

This application claims the benefit of priority to Korean Patent Application Nos. 10-2014-0162834, filed with the Korean Intellectual Property Office on Nov. 20, 2014, the entirety of which is incorporated herein by reference.

### TECHNICAL FIELD

The present disclosure relates to a conductive paste for an internal electrode, a piezoelectric element, and a piezoelectric vibration module including the same.

### BACKGROUND

In general, a piezoelectric ceramic for a piezoelectric element should have a high piezoelectric constant and a high electromechanical coupling coefficient. Furthermore, although it may depend on the type of material used for the internal electrode, the piezoelectric ceramic should also have excellent piezoelectric properties even if the piezoelectric ceramic is co-fired at a temperature of 1000° C. or lower, in order to use the piezoelectric ceramic in a multi-layer piezoelectric element.

Conventional lead zirconate titanate (PZT) piezoelectric ceramics have sintering temperatures of 1100° C. or higher. Accordingly, for multi-layer piezoelectric elements using PZT ceramics, the internal electrodes need to be made of high-cost materials having a melting point higher than the sintering temperature of 1100° C.

Accordingly, there have been studies into adding novel materials to conventional PZT to lower the sintering temperature while maintaining the material's piezoelectric properties.

In addition, there have been ongoing efforts to increase the number of layers in the multi-layer piezoelectric elements in order to minimize the installation areas to cope with electronic products that have become increasingly smaller.

The related art of the present disclosure is disclosed in Korean Patent Publication No. 10-2006-0125750 (laid open on Dec. 6, 2006).

### SUMMARY

According to one embodiment of the present subject matter, a sintering temperature of a common material may be higher than a sintering temperature of a conductive material, and thus it is possible to control a contraction ratio of an internal electrode layer and also minimize a coagulation of the common material.

Moreover, it is possible to prevent the internal electrode layer from becoming discontinuous and it is possible to implement a high coverage of the internal electrode layer.

### BRIEF DESCRIPTION OF DRAWINGS

FIG. 1 is a graph showing the binary condition of lead oxide (PbO) and copper oxide (CuO) that are applied as a eutectic mixture to a conductive paste.

FIG. 2 is a graph showing the relationship between a curvature and a weight percentage of a common material in the conductive paste, based on a total weight of the conductive paste.

FIG. 3 shows the relationship between coverage of an internal electrode layer and a weight percentage of the eutectic mixture, based on a total weight of the common material in the conductive paste.

FIG. 4 is a cross-sectional view showing a piezoelectric element in accordance with an embodiment of the present inventive concept.

FIG. 5 is a magnified view of section A shown in FIG. 4.

FIG. 6 shows a piezoelectric vibration module in accordance with an embodiment of the present inventive concept.

### DETAILED DESCRIPTION

The terms used in the description are intended to describe certain embodiments only, and shall by no means restrict the present inventive concept. Unless clearly used otherwise, expressions in a singular form also include the plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

When one element is described as being “coupled” or “connected” to another element, it shall be construed as not only being in physical contact with the other element but also as possibly having a third element interposed therebetween and each of the one element and the other element being in contact with the third element.

Hereinafter, certain embodiments of a conductive paste, a piezoelectric element and a piezoelectric vibration module having the same in accordance with the present inventive concept will be described in detail with reference to the accompanying drawings. In describing certain embodiments of the present inventive concept with reference to the accompanying drawings, any identical or corresponding elements will be assigned with same reference numerals, and their redundant description will not be provided.

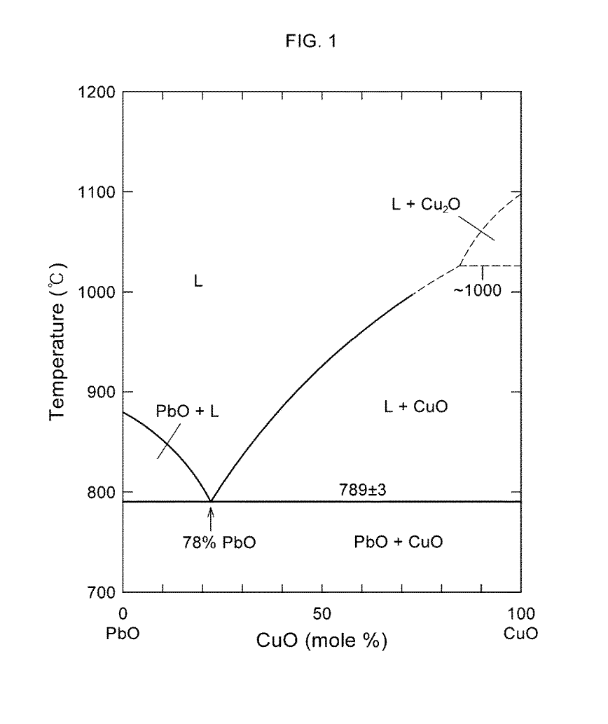

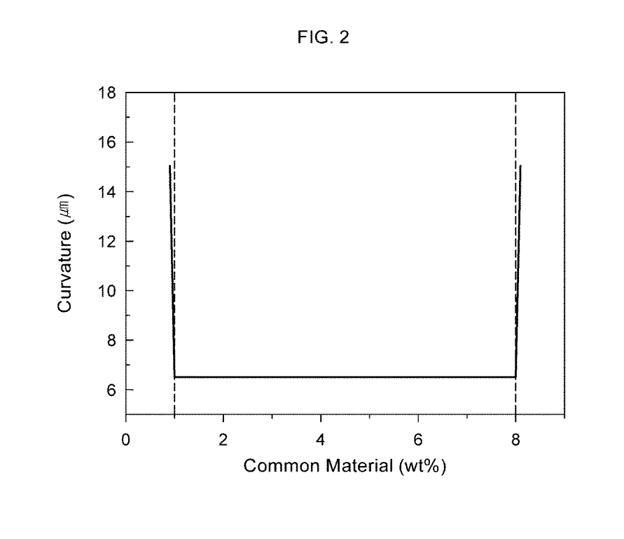

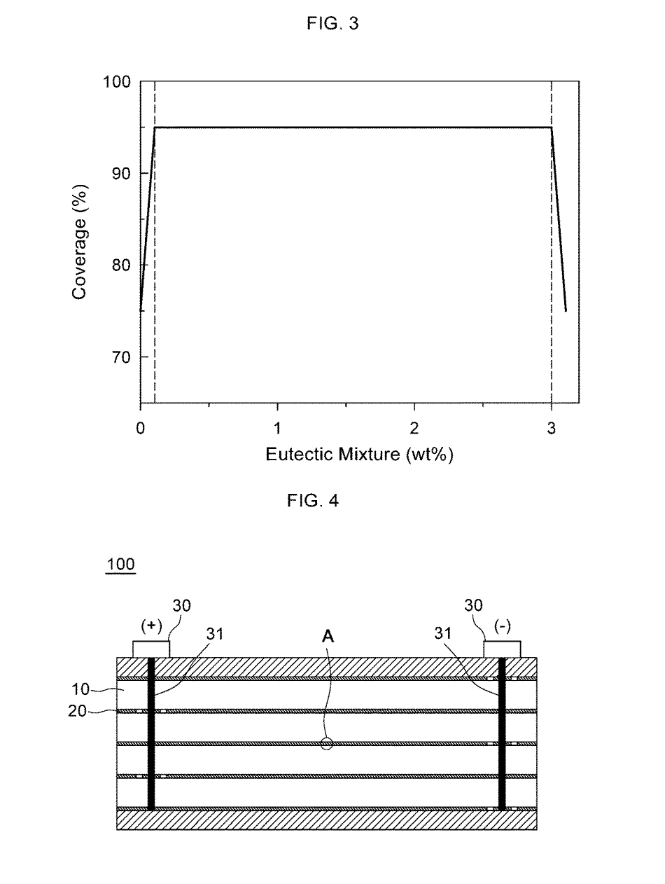

FIG. 1 is a graph showing the binary condition of lead oxide (PbO) and copper oxide (CuO) that are applied as a eutectic mixture to a conductive paste in accordance with an embodiment of the present inventive concept. FIG. 2 is a graph showing the relationship between a curvature and a weight percentage (wt %) of a common material in the conductive paste in accordance with an embodiment of the present inventive concept. FIG. 3 shows the relationship between the coverage of an internal electrode layer based on a weight percentage of the eutectic mixture in the conductive paste in accordance with an embodiment of the present inventive concept.

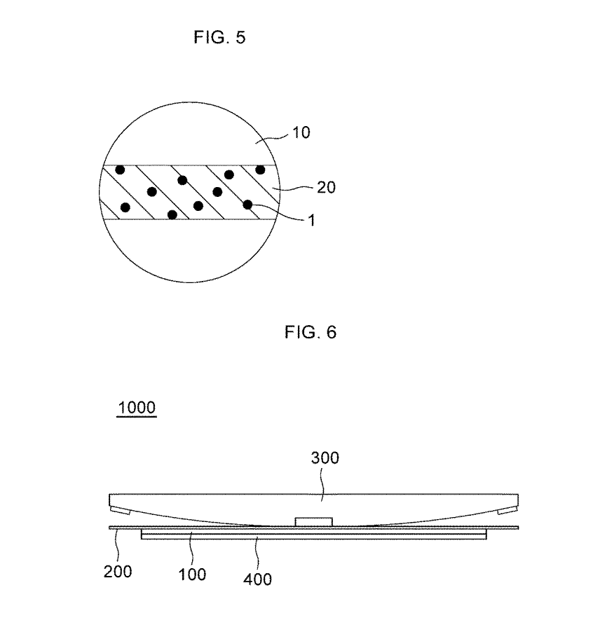

As illustrated in FIG. 5, the conductive paste for an internal electrode in accordance with an embodiment of the present inventive concept includes a conductive material and a common material 1. The conductive material, which is a material having electrical conductivity, allows an electric charge to be applied to an internal electrode layer 20, which will be further described below. There is no restriction on the form of the conductive material, which may be in a powder form.

It will be further described below that in the case where a piezoelectric layer 10 is formed using a piezoelectric ceramic, the conductive material may be a single metal or a metal alloy having a melting point that is higher than or equal to the sintering temperature of the piezoelectric ceramic.

Here, the conductive material may include a palladium-silver (Pd—Ag) alloy. The content of palladium in the Pd—Ag alloy may vary according to the requirements of the design.

Moreover, the conductive material may be made of at least one metal selected from the group consisting of Pd, Pt, Ru, Ir, Au, Ni, Mo, W, Al, Ta, Ag and Ti or a conductive oxide or a conductive nitride of at least one metal selected from the group consisting of Pd, Pt, Ru, Ir, Au, Ni, Mo, W, Al, Ta, Ag and Ti.

The common material 1 may comprise a dielectric substance and a eutectic mixture. The common material 1 may be added to the conductive paste in accordance with the present embodiment and may prevent a ceramic element from warping that may occur when the conductive material is sintered.

Here, that the conductive material is sintered may mean that a neck is formed at a portion where conductive materials are in contact with one another and necking particles begin to grow.

In a piezoelectric element 100, which will be further described below, the piezoelectric layer 10 and the internal electrode layer 20 may have different contraction ratios when sintered together because the piezoelectric layer 10 and the internal electrode layer 20 may be constituted of different materials. This may not be a serious problem when the piezoelectric element 100 has a relatively low number of layers, but when the piezoelectric element 100 includes a greater number of layers, the area joined by the piezoelectric layer 10 and the internal electrode layer 20 increases in proportion to the number of layers, increasing the probability that warpage will occur due to the difference in contraction ratios between the piezoelectric layer 10 and the internal electrode layer 20.

Accordingly, the difference in contraction ratios between the piezoelectric layer 10 and the internal electrode layer 20 may be reduced by forming the internal electrode layer 20 from the conductive paste including the common material 1, which includes a dielectric substance.

The dielectric substance may have Pb(Zr, Ti)O₃ (lead zirconate titanate, PZT) as a main component thereof. In other words, the dielectric substance may be a Pb(Ni, Nb)—Pb(Zr, Ti)O₃ (lead nickel nicobate zirconate titanate, PNN-PZT) piezoelectric ceramic, a Pb(Mg, Nb)—Pb(Zr, Ti)O₃ (lead magnesium niobate zirconate titanate, PMN-PZT) piezoelectric ceramic, or a Pb(Mg, Nb)—Pb(Ni, Nb)—Pb(Zr, Ti)O₃ (lead magnesium nickel niobate zirconate titanate, PMN-PNN-PZT) piezoelectric ceramic to which a relaxor is added. Moreover, the dielectric substance may be a lead-free piezoelectric ceramic.

The eutectic mixture, which is a multi-component system material included in the common material 1, may include lead oxide (PbO) and copper oxide (CuO). The eutectic temperature of the eutectic mixture is higher than a sintering temperature of the conductive material. That is, a eutectic mixture having a higher eutectic temperature than the sintering temperature of the conductive material may be added as a sintering additive to the common material 1.

When the sintering temperature of the conductive material is higher than the sintering temperature of the common material 1, the common material 1 may be sintered first, possibly causing coagulation of the common material 1. In such a case, the internal electrode layer 20 may not be continuously connected. Accordingly, the coagulation of the common material 1 may be prevented by adding a eutectic mixture having a higher eutectic temperature than the sintering temperature of the conductive material to the common material 1 as a sintering additive.

Referring to FIG. 1, for a binary eutectic mixture constituted with PbO—CuO, the eutectic temperature is near 790° C., and thus the eutectic mixture may be liquefied at the temperature of 790° C. As a result, the common material 1 may be sintered at the temperature near 790° C.

Although the binary eutectic mixture constituted from PbO and CuO is illustrated in FIG. 2, the eutectic mixture in accordance with the present embodiment may possibly be a ternary material including PbO and CuO.

Here, the content of the common material 1 contained in the conductive paste may be between 1 wt % and 8 wt %, based on a total weight of the conductive paste.

FIG. 2 illustrates that curvature sharply increases when the content of the common material 1 is less than 1 wt % or greater than 8 wt % in the conductive paste, in accordance with the present embodiment.

Here, the curvature may be defined as an absolute value of the difference between a center height of the internal electrode layer 20 and an average of end heights of the internal electrode layer 20, when the internal electrode layer 20 is formed by sintering the conductive paste.

Furthermore, the content of the eutectic mixture contained in the common material 1 may be between 0.1 wt % and 3 wt %, based on a total weight of the common material 1.

FIG. 3 illustrates the coverage of the internal electrode layer 20 based on the weight percentage of the eutectic mixture. The weight percentage (wt %) of the eutectic mixture means a percentage of weight of the eutectic mixture, based on a total weight of the common material 1. The coverage means a proportion of an area of the internal electrode layer 20 formed on one surface of the piezoelectric layer 10. A low coverage means that the area of the internal electrode layer 20 formed on the one surface of the piezoelectric layer 10 is small.

With a given area of the conductive paste formed on one surface of the piezoelectric layer 10, a smaller area of the internal electrode layer 20 may be formed, and the coverage may be reduced, if the common material 1 coagulates when the conductive paste is sintered.

When the weight percentage of the eutectic mixture is less than 0.1 wt % or greater than 3 wt %, the common material 1 may coagulate, and the coverage may be reduced.

If the coverage is reduced, the reliability of the element may be jeopardized, and thus the weight percentage of the eutectic mixture is limited as described above.

Accordingly, as the conductive paste for an internal electrode in accordance with an embodiment of the present inventive concept includes the common material 1, it is possible to prevent a contraction from occurring in the internal electrode layer 20 when the conductive paste is sintered.

Moreover, since the eutectic temperature of the eutectic mixture is higher than the sintering temperature of the conductive material, it is possible to prevent the common material 1 from being sintered ahead of the conductive material. Accordingly, it is possible to prevent the common material 1 from coagulating, allowing the internal electrode layer 20 to have a high coverage and a continuous connection.

FIG. 4 is a cross-sectional view showing a piezoelectric element in accordance with one embodiment of the present inventive concept. FIG. 5 is a magnified view of section A shown in FIG. 4.

As illustrated in FIG. 4 and FIG. 5, the piezoelectric element 100 includes the piezoelectric layer 10 and the internal electrode layer 20.

The piezoelectric layer 10 may include a piezoelectric ceramic. When an electric charge is applied to internal electrode layers 20 formed, respectively, on an upper surface and a lower surface of the piezoelectric layer 10, a mechanical displacement may occur in the piezoelectric layer 10.

The piezoelectric ceramic may have PZT as a main component thereof. In other words, the piezoelectric ceramic may be a PNN-PZT piezoelectric ceramic, a PMN-PZT piezoelectric ceramic, or a PNN-PMN-PZT piezoelectric ceramic to which a relaxor is added. Moreover, the piezoelectric ceramic may be a lead-free piezoelectric ceramic.

The piezoelectric ceramic may be produced by proportionally weighing, primarily ball milling, mixing and calcining the raw materials, for example, lead oxide (PbO), zirconium oxide (ZrO₂), etc.

The piezoelectric ceramic may be pulverized and have a binder or the like added thereto before being made into a slurry form and then processed to form a sheet. Here, since the sintering temperature of PZT is high, a sintering additive may be added to the slurry for low-temperature sintering. For example, a eutectic mixture containing lithium carbonate (Li₂CO₃) and calcium carbonate (CaCO₃) may be added as a sintering additive.

The internal electrode layer 20 is made of the conductive paste, which includes the conductive material and the common material 1 composed of the dielectric substance and the eutectic mixture, and may be formed in between piezoelectric layers 10 that are adjacent to each other. In other words, the internal electrode layer 20 may be formed by sintering the conductive paste, as described above.

Here, the dielectric substance may have the same composition as the piezoelectric ceramic.

While FIG. 5 shows the common material 1 that is present in the internal electrode layer 20, the common material 1 may include the dielectric substance, and the piezoelectric layer 10 may include the piezoelectric ceramic, as described above. Accordingly, in the case where the dielectric substance is composed of the same material as the piezoelectric ceramic, the compositions of the piezoelectric layer 10 and the common material 1 are similar to each other, making it possible to prevent a phenomenon such as exfoliation caused by a difference between the contraction ratios of the internal electrode layer 20 and the piezoelectric layer 10.

Moreover, since the common material 1 may be connected with the piezoelectric layer 10 on a surface of the internal electrode layer 20, it is possible to prevent the piezoelectric element 10 from warping.

The content of the common material 1 contained in the conductive paste may be between 1 wt % and 8 wt %, based on a total weight of the conductive paste, and the eutectic mixture contained in the common material 1 may be between 0.1 wt % and 3 wt %, based on a total weight of the common material 1.

The piezoelectric element 100 may further include external electrodes 30 connected with the internal electrode layer 20.

While FIG. 4 illustrates an embodiment wherein the external electrodes 30 are formed on an upper surface of the piezoelectric element 100, the external electrodes 30 may also be formed, if necessary, on a lateral surface(s) of the piezoelectric element 100. The external electrodes 30 may also be formed by being connected to a lateral surface and an upper surface of the piezoelectric element 100. Moreover, although the embodiment illustrated in FIG. 4 includes the external electrode 30 on the left side having a positive polarity and the external electrode 30 on the right side having a negative polarity, the external electrodes 30 may also be formed to have the external electrode 30 on the left side having a negative polarity and the external electrode 30 on the right side having a positive polarity.

Because the external electrodes 30 may be formed after the piezoelectric element 100 is sintered, the external electrodes 30 may be formed using a material having a relatively low melting point, unlike the internal electrode layer 20. In other words, copper, silver, or an alloy thereof may be used for the external electrodes 30.

The external electrodes 30 may include via holes 31 in order to be connected with the internal electrode layer 20. Here, the via holes 31 may be alternately connected to the internal electrode layers 20 so that different electric charges are applied, respectively, to internal electrode layers 20 that are adjacent to each other. For this, a pattern may be formed on the internal electrode layer 20 in such a way that a particular internal electrode layer 20 is connected with a particular via hole 31 only.

As a result, the piezoelectric element 100 may prevent a warpage caused by a difference in contraction ratio between the piezoelectric layer 10 and the internal electrode layer 20.

Moreover, it is possible to prevent the common material 1 from coagulating by adding the eutectic mixture having a higher eutectic temperature than the sintering temperature of the conductive material to the common material 1. Moreover, this may also prevent disconnection of the internal electrode layer 20.

Furthermore, since the common material 1 can inhibit the contraction that may occur when the conductive paste is sintered, the coverage of the internal electrode layer 20 may be improved.

FIG. 6 shows a piezoelectric vibration module in accordance with one embodiment of the present inventive concept.

As illustrated in FIG. 6, a piezoelectric vibration module 1000 may include a piezoelectric element 100, a vibrating plate 200, a weight 300 and a substrate 400.

The piezoelectric element 100 is configured to generate mechanical displacement when electric power is supplied by the substrate, which will be further described below.

The vibrating plate 200 is coupled to the piezoelectric element 100 such that deformation of the piezoelectric element 100 causes displacement of the vibrating plate 200 in a direction orthogonal to the deformation of the piezoelectric element 100.

The vibrating plate 200 may be made of a metallic material, such as SUS (Steel Use Stainless), which has elasticity, in order to be deformed integrally with the piezoelectric element 100, which exhibits tensile and compression strain when electric charge is applied thereto.

When the vibrating plate 200 and the piezoelectric element 100 are bonded together, the vibrating plate 200 may include invar, which has a similar coefficient of thermal expansion to that of the piezoelectric element 100, in order to prevent a bending phenomenon that may result when an adhesive material is hardened.

The weight 300 is configured to increase vibrations caused by the displacement of the vibrating plate 200.

In order to maximize the vibrations, the weight 300 may have a center portion thereof coupled to a maximum displacement point of the vibrating plate 200, which is where the maximum displacement occurs due to the tensile and compression strain of the piezoelectric element 100.

The weight 300 may be made of a steel material. In one embodiment, the weight 300 may be made of a material containing tungsten, which has a relatively high density.

The substrate 400 may be coupled to the piezoelectric element 100 so as to supply electrical power to the piezoelectric element 100. The substrate 400 may be a flexible board to account for the deformation that may occur in the piezoelectric element 100.

The substrate 400 may adjust the vibrations of the piezoelectric vibration module 1000 by controlling electrical signals applied to the piezoelectric element 100. That is, the intensity of vibrations may be adjusted by controlling the frequency of the electrical signals supplied to the piezoelectric element 100, and the duration of the vibrations may be adjusted by controlling the amount of time the electrical signals are supplied to the piezoelectric element 100.

Although certain embodiments of the present inventive concept have been described, it may be appreciated that a number of permutations and modifications of the present inventive concept are possible by those who are ordinarily skilled in the art to which the present inventive concept pertains. These permutations and modifications may be obtained by supplementing, modifying, deleting and/or adding some elements without departing from the technical ideas of the present inventive concept that are disclosed in the claims appended below. Such permutations and modifications are also covered by the scope of the present inventive concept.

What is claimed is:

1. A conductive paste for an internal electrode, comprising:
a conductive material; and
a common material comprising a dielectric substance and a eutectic mixture,
wherein the eutectic mixture comprises lead oxide (PbO) and copper oxide (CuO) and has a eutectic temperature that is higher than a sintering temperature of the conductive material.

2. The conductive paste of claim 1, wherein a content of the common material contained in the conductive paste is between 1 wt % and 8 wt %, based on a total weight of the conductive paste.

3. The conductive paste of claim 2, wherein a content of the eutectic mixture contained in the common material is between 0.1 wt % and 3 wt %, based on a total weight of the common material.

4. The conductive paste of claim 1, wherein the conductive material comprises a palladium-silver (Pd—Ag) alloy.

5. The conductive paste of claim 2, wherein the conductive material comprises a palladium-silver (Pd—Ag) alloy.

6. The conductive paste of claim 3, wherein the conductive material comprises a palladium-silver (Pd—Ag) alloy.

7. A piezoelectric element comprising:
a piezoelectric layer comprising a piezoelectric ceramic; and
an internal electrode layer comprising a conductive paste and disposed between the piezoelectric layer and an adjacent piezoelectric layer, the conductive paste comprising a common material and a conductive material, the common material comprising a dielectric substance and a eutectic mixture,
wherein the eutectic mixture comprises lead oxide (PbO) and copper oxide (CuO) and has a eutectic temperature that is higher than a sintering temperature of the conductive material.

8. The piezoelectric element of claim 7, wherein the dielectric substance has a same composition as the piezoelectric ceramic.

9. The piezoelectric element of claim 7, wherein a content of the common material is between 1 wt % and 8 wt %, based on a total weight of the conductive paste.

10. The piezoelectric element of claim 9, wherein a content of the eutectic mixture is between 0.1 wt % and 3 wt %, based on a total weight of the common material.

11. The piezoelectric element of claim 7, wherein the conductive material comprises a palladium-silver (Pd—Ag) alloy.

12. A piezoelectric vibration module comprising:
a piezoelectric element according to claim 7;
a vibrating plate coupled to the piezoelectric element such that a deformation of the piezoelectric element causes a displacement of the vibrating plate in a direction orthogonal to the deformation of the piezoelectric element;
a weight configured to increase vibrations caused by the displacement of the vibrating plate; and
a substrate coupled to the piezoelectric element and configured to supply electric power to the piezoelectric element.

13. A piezoelectric vibration module comprising:
a piezoelectric element according to claim 8;
a vibrating plate coupled to the piezoelectric element such that a deformation of the piezoelectric element causes a displacement of the vibrating plate in a direction orthogonal to the deformation of the piezoelectric element;
a weight configured to increase vibrations caused by the displacement of the vibrating plate; and
a substrate coupled to the piezoelectric element and configured to supply electric power to the piezoelectric element.

14. A piezoelectric vibration module comprising:
a piezoelectric element according to claim 9;
a vibrating plate coupled to the piezoelectric element such that a deformation of the piezoelectric element causes a displacement of the vibrating plate in a direction orthogonal to the deformation of the piezoelectric element;
a weight configured to increase vibrations caused by the displacement of the vibrating plate; and
a substrate coupled to the piezoelectric element and configured to supply electric power to the piezoelectric element.

15. A piezoelectric vibration module comprising:
a piezoelectric element according to claim 10;
a vibrating plate coupled to the piezoelectric element such that a deformation of the piezoelectric element causes a displacement of the vibrating plate in a direction orthogonal to the deformation of the piezoelectric element;
a weight configured to increase vibrations caused by the displacement of the vibrating plate; and
a substrate coupled to the piezoelectric element and configured to supply electric power to the piezoelectric element.

16. A piezoelectric vibration module comprising:
a piezoelectric element according to claim 11;
a vibrating plate coupled to the piezoelectric element such that a deformation of the piezoelectric element causes a displacement of the vibrating plate in a direction orthogonal to the deformation of the piezoelectric element;
a weight configured to increase vibrations caused by the displacement of the vibrating plate; and
a substrate coupled to the piezoelectric element and configured to supply electric power to the piezoelectric element.

17. A method for forming a piezoelectric element, the method comprising steps of:
forming a conductive paste comprising a conductive material and a common material, wherein the common material comprises a dielectric substance and a eutectic mixture and the eutectic mixture comprises lead oxide (PbO) and copper oxide (CuO) and has a eutectic temperature that is higher than a sintering temperature of the conductive material,
sintering the conductive paste on a piezoelectric layer to form an internal electrode, wherein the piezoelectric layer comprises a piezoelectric ceramic, and
forming external electrodes on a surface of the piezoelectric element, wherein the external electrodes are connected to the internal electrodes.

18. The method of claim 17, wherein a content of the common material contained in the conductive paste is between 1 wt % and 8 wt %, based on a total weight of the conductive paste.

19. The method of claim 17, wherein a content of the eutectic mixture contained in the common material is between 0.1 wt % and 3 wt %, based on a total weight of the common material.

20. The method of claim 17, wherein the piezoelectric ceramic has a same composition as the dielectric substance.
